(19) United States
(12) Patent Application Publication
(10) Pub. No.: US 2018/0005687 A1
(43) Pub. Date: Jan. 4, 2018

(54) SEMICONDUCTOR DEVICE AND METHOD OF CONTROLLING SEMICONDUCTOR DEVICE

(71) Applicant: FUJITSU LIMITED, Kawasaki-shi (JP)

(72) Inventor: Yukihito KAWABE, Kawasaki (JP)

(73) Assignee: FUJITSU LIMITED, Kawasaki-shi (JP)

(21) Appl. No.: 15/631,465

(22) Filed: Jun. 23, 2017

(30) Foreign Application Priority Data
Jul. 1, 2016 (JP) 2016-131906

(51) Int. Cl. G11C 11/4076; G11C 11/406; G11C 7/04; G11C 7/22; H03K 3/03; H03K 3/011

(52) U.S. Cl. CPC G11C 11/4076; H03K 3/0315; H03K 3/011; G11C 7/04; G11C 7/222; G11C 11/406

(57) ABSTRACT

A semiconductor device includes an oscillator that oscillates to generate a clock, a circuit that operates based on the clock generated by the oscillator, a temperature detector that detects the temperature of the circuit, a power detector that acquires, as a monitored power value, power consumed by the circuit, and a frequency controller that controls, when the temperature detected by the temperature detector exceeds a temperature threshold, the frequency of the clock of the oscillator so that the monitored power value matches target power that causes the temperature of the circuit to converge to a temperature higher than the temperature threshold.

### CROSS-REFERENCE TO RELATED APPLICATION

This application is based upon and claims the benefit of priority of the prior Japanese Patent Application No. 2016-131906, filed on Jul. 1, 2016, the entire contents of which are incorporated herein by reference.

### FIELD

The embodiment discussed herein is related to a semiconductor device and a method of controlling a semiconductor device.

### BACKGROUND

With improvements in the performance of semiconductor devices such as processors, power to be consumed by semiconductor devices tends to increase from year to year, and a problem in which, due to upper limits of power supply capacities and upper limits of chip temperatures, semiconductor devices may not operate with maximum loads with which the semiconductor devices are able to operate according to specifications has arisen. A processor such as a central processing unit or a micro processing unit (MPU) is described below as a semiconductor device as an example.

The processor is requested to operate so that power consumed by the processor and the temperature of the processor do not exceed upper limits. If the consumed power or the temperature exceeds a corresponding upper limit, the processor may erroneously operate due to an increase in a delay or skew in a critical path. In a state in which there is a possibility that the consumed power or the temperature may exceed a corresponding upper limit during a normal operation of the processor, a load is adjusted so that the consumed power and the temperature do not exceed the upper limits. As methods of adjusting the load, dynamic frequency scaling (DFS) and dynamic voltage and frequency scaling (DVFS) are known. DFS is a method of changing the load by dynamically changing a clock frequency. DVFS is a method of reducing an operational voltage by a voltage value corresponding to a timing margin obtained by a reduction in a clock frequency and reducing power to be consumed.

In the aforementioned methods, it is desirable that the processor operate with a clock frequency as high as possible for the performance of the processor so that the load does not exceeds an upper limit of the load. As a control method of causing the processor to operate with the clock frequency as high as possible so that the load does not exceeds the upper limit, a method of starting control to reduce the clock frequency or a power supply voltage when the load exceeds a load threshold lower than the upper limit is executed in general. In this method, the clock frequency or the power supply voltage is reduced and the load is reduced in response to the reduction in the clock frequency or the power supply voltage. If the temperature of the processor limits an operation of the processor, a temperature threshold for control is set and a process of reducing the clock frequency when the temperature of the processor exceeds the temperature threshold is executed. However, even if the clock frequency is reduced when the temperature exceeds the temperature threshold, the actual reduction in the clock frequency is delayed and the temperature continues to increase during the delay.

In this control, if the temperature threshold is reduced, the performance of the processor is steadily reduced. It is thus preferable that the temperature threshold be close to the upper limit of the temperature. However, if the temperature threshold is too close to the upper limit of the temperature, the temperature of the processor may exceed the upper limit within a time period from the time when the temperature of the processor exceeds the temperature threshold to the time when the clock frequency is reduced. Thus, the temperature threshold is reduced by a temperature value or more by which the temperature of the processor increases during the delay in the frequency control, compared with the upper limit of the temperature.

The temperature of the processor increases by the maximum temperature value estimated in the aforementioned temperature control when the consumed power changes to the maximum value in a step-by-step manner due to a variation in the load. In this case, when the temperature of the processor exceeds the temperature threshold, the clock frequency is reduced to a frequency that causes the temperature of the processor consuming the maximum power to be lower than the upper limit of the temperature.

If the power consumed by the processor when the temperature of the processor exceeds the temperature threshold is lower than the maximum consumed power, the clock frequency is not controlled in the aforementioned manner. However, if the frequency control is executed based on only the detected temperature, it is difficult to determine a value to which the temperature of the processor finally increases when the temperature of the processor exceeds the temperature threshold, and the clock frequency is reduced to the aforementioned frequency so that the temperature does not exceed the upper limit even upon the maximum variation in the load. Thus, this control results in a reduction in the performance of the processor.

As measures against the aforementioned problems, a method of indirectly estimating a change in the temperature by measuring the difference between the time when the temperature exceeds one of multiple temperature thresholds and the time when the temperature exceeds the other temperature threshold is known. It is known that an operation of a semiconductor device is limited based on a first temperature state in which the temperature of the semiconductor device is equal to or lower than 50° C., a second temperature state in which a rapid change in the temperature of the semiconductor device is detected, a third temperature state in which the temperature of the semiconductor device is equal to or higher than 80° C., and a fourth temperature state in which the temperature of the semiconductor device is equal to or higher than 100° C. In this example, the number of operations, to be limited, of the semiconductor device may be gradually increased from the number of operations in the first temperature state to the number of operations in the fourth temperature state. In this example, however, since the limitation of operations of the semiconductor device is not based on a change, due to an increase in an amount to be processed, in the temperature, the actual temperature threshold may be reduced due to an increase in a margin, a control delay may increase, and the performance of the semiconductor may be reduced.

A semiconductor device is known, which controls a clock frequency based on the difference between times when power consumed by a circuit section is monitored if the temperature of the circuit section that is detected by a temperature sensor exceeds a predetermined value. The semiconductor device controls the clock frequency to forcibly significantly reduce the clock frequency and significantly reduce power to be consumed when the temperature of the circuit section continuously exceeds a temperature threshold for a certain time period.

However, when the temperature detected by the sensor exceeds the predetermined value and the clock frequency is forcibly significantly reduced, the performance of the semiconductor device may be pointlessly reduced due to the reduction in the frequency.

The followings are reference documents.
[Document 1] Japanese Laid-open Patent Publications No. 2015-165405 and
[Document 2] Japanese Laid-open Patent Publications No. 2015-130035.

### SUMMARY

According to an aspect of the invention, a semiconductor device includes: an oscillator that oscillates to generate a clock; a circuit that operates based on the clock generated by the oscillator; a temperature detector that detects the temperature of the circuit; a power detector that acquires, as a monitored power value, power consumed by the circuit; and a frequency controller that controls, when the temperature detected by the temperature detector exceeds a temperature threshold, the frequency of the clock of the oscillator so that the monitored power value matches target power that causes the temperature of the circuit to converge to a temperature higher than the temperature threshold.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a block diagram of a semiconductor device related to a semiconductor device according to an embodiment;

FIG. 2 is a flowchart of a frequency control process to be executed by a frequency determiner illustrated in FIG. 1;

FIG. 3 is a diagram illustrating timing charts when the frequency determiner executes processes of S201 and S202 illustrated in FIG. 2 based on a change in a monitored power value;

FIG. 4 is a block diagram of an electronic device including the semiconductor device according to the embodiment;

FIG. 5 is a diagram illustrating an example of an internal circuit of a power monitor illustrated in FIG. 4;

FIG. 6 is an internal circuit block diagram of a frequency controller illustrated in FIG. 4;

FIG. 7 is an internal circuit block diagram of an exponential moving average filter illustrated in FIG. 4;

FIG. 8A is an internal circuit block diagram of a first frequency calculator illustrated in FIG. 4;

FIG. 8B is an internal circuit block diagram of a second frequency calculator illustrated in FIG. 4;

FIG. 9 is a diagram illustrating an example of an internal configuration of a frequency determiner illustrated in FIG. 4;

FIG. 10A is a diagram illustrating an internal configuration of a state machine illustrated in FIG. 9;

FIG. 10B is a diagram describing transitions between states of the state machine illustrated in FIG. 9;

FIG. 11 is a flowchart of a frequency control process to be executed by the semiconductor device illustrated in FIG. 4;

FIG. 12 is a diagram illustrating timing charts when the frequency controller illustrated in FIG. 4 executes processes of S202 to S210 based on a change in a monitored power value;

FIG. 13A is a first diagram describing an effect of the semiconductor device illustrated in FIG. 4; and

FIG. 13B is a second diagram describing the effect of the semiconductor device illustrated in FIG. 4.

### DESCRIPTION OF EMBODIMENT

Before an embodiment is described, a semiconductor related to a semiconductor device according to the embodiment is described. The technical scope of the present disclosure is not limited to the embodiment.

Configuration and Functions of Related Semiconductor Device

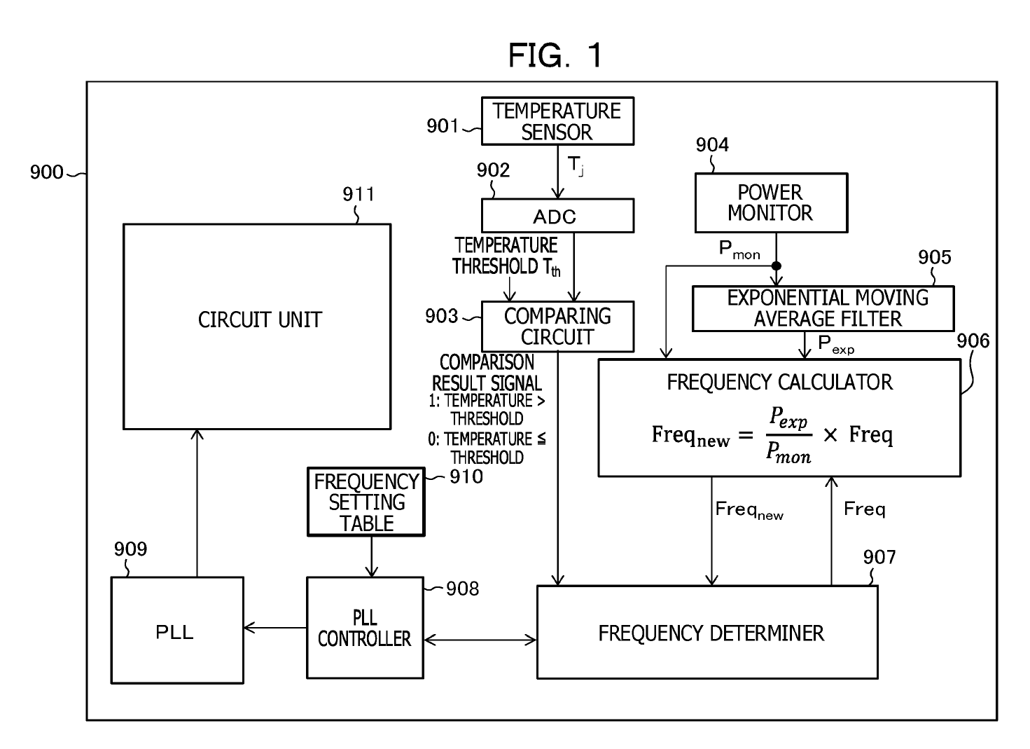

FIG. 1 is a block diagram of the semiconductor device related to the semiconductor device according to the embodiment.

The semiconductor device 900 includes a temperature sensor 901, an analog-to-digital (AD) converter 902, a comparing circuit 903, a power monitor 904, an exponential moving average filter 905, a frequency calculator 906, and a frequency determiner 907. The semiconductor device 900 further includes a phase locked loop (PLL) controller 908, a PLL 909, and a circuit section 911. The PLL controller 908 is able to acquire a frequency from a frequency setting table 910. The circuit section 911 receives a clock from the PLL 909.

The temperature sensor 901 detects the temperature of the circuit section 911 and outputs a temperature signal indicating the detected temperature Tⱼ to the AD converter 902. The AD converter 902 converts the temperature signal received from the temperature sensor 901 from an analog signal to a digital signal. The comparing circuit 903 compares a temperature threshold Tₜₕ with the detected temperature Tⱼ corresponding to the temperature signal converted to the digital signal by the AD converter 902. The temperature threshold Tₜₕ is a value able to be set by an operator (not illustrated) so that even when an operation of the circuit section 911 changes and power consumed by the circuit section 911 reaches the maximum power amount, the temperature of the semiconductor device 900 does not exceed an upper limit of the temperature of the semiconductor device 900. If the detected temperature Tⱼ corresponding to the temperature signal is higher than the temperature threshold Tₜₕ, the comparing circuit 903 outputs a comparison result signal indicating a signal value “1” to the frequency determiner 907. If the detected temperature Tⱼ corresponding to the temperature signal is equal to or lower than the temperature threshold Tₜₕ, the comparing circuit 903 outputs the comparison result signal indicating a signal value “0” to the frequency determiner 907. Since various elements including the AD converter 902 exist between the temperature sensor 901 and the frequency determiner 907, a certain delay time from the time when the temperature sensor 901 detects the temperature of the circuit section 911 to the time when the comparison result signal is input to the frequency determiner 907 occurs.

The power monitor 904 includes a plurality of registers, a plurality of multipliers, and an adder. The power monitor 904 acquires operation rate information of signals having high correlations with power consumed by sections of a chip. The multipliers multiply the operation rate information by appropriate weight coefficients stored in the registers. The adder calculates the total of values obtained by multiplying the operation rates by the weight coefficients. The total corresponds to or nearly corresponds to a dynamic power value of the chip. The power monitor 904 outputs a monitored power value signal indicating the calculated monitored power value Pₘₒₙ to the exponential moving average filter 905 and the frequency calculator 906.

The exponential moving average filter 905 calculates an exponential moving average or one of moving averages and outputs an exponential moving average signal indicating the calculated exponential moving average power value Pₑₓₚ to the frequency calculator 906. As described later in detail, in the exponential moving average filter 905, a time constant τ is defined to correspond to a thermal time constant of the semiconductor device 900, and the exponential moving average power value Pₑₓₚ indicates power corresponding to a change, based on a change in the monitored power value Pₘₒₙ, in the temperature of the circuit section 911. The exponential moving average filter 905 outputs the exponential moving average power signal indicating the exponential moving average power value Pₑₓₚ after delaying the exponential moving average power signal for a delay time corresponding to a time period from the time when the temperature sensor 901 detects the temperature Tⱼ to the time when the comparison result signal is input to the frequency determiner 907. Since the exponential moving average filter 905 outputs the exponential moving average power signal after delaying the exponential moving average power signal, the exponential moving average power value Pₑₓₚ corresponding to the exponential moving average signal may change in synchronization with a change in the temperature of the circuit section 911.

The frequency calculator 906 calculates a change frequency Freq_{new} from the monitored power value Pₘₒₙ received from the power monitor 904, the exponential moving average power value Pₑₓₚ received from the exponential moving average filter 905, and the current frequency Freq received from the frequency determiner 907. The change frequency Freq_{new} is expressed by Equation (1).

$${Freq}_{new} = \frac{{P}_{exp}}{{P}_{mon}} \times Freq \qquad ( 1 )$$

The frequency determiner 907 outputs, to the PLL controller 908, a frequency change instruction signal indicating an instruction to change the frequency of the PLL 909, based on the signal value of the comparison result signal received from the comparing circuit 903. When receiving the frequency change instruction signal from the frequency determiner 907, the PLL controller 908 uses the frequency setting table 910 to change the frequency of the PLL 909 based on the instruction corresponding to the frequency change instruction signal. The PLL 909 changes the frequency under control by the PLL controller 908.

Operations of Related Semiconductor Device

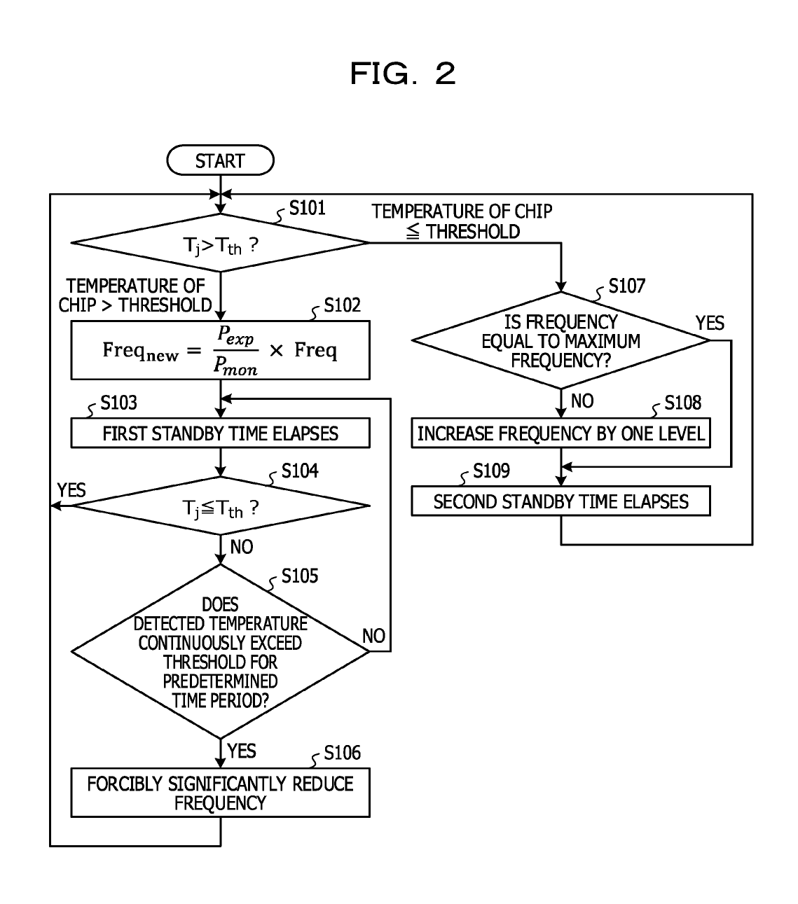

FIG. 2 is a flowchart of a frequency control process to be executed by the frequency determiner 907.

First, the frequency determiner 907 determines whether or not the temperature Tⱼ detected by the temperature sensor 901 is higher than the temperature threshold Tₜₕ (in S101). Specifically, the frequency determiner 907 determines whether the signal value of the comparison result signal received from the comparing circuit 903 is “0” or “1”. If the frequency determiner 907 determines that the detected temperature Tⱼ is higher than the temperature threshold Tₜₕ (YES in S101), the frequency determiner 907 outputs, to the PLL controller 908, the frequency change instruction signal indicating an instruction to change the oscillation frequency of the PLL 909 from the current frequency Freq to the change frequency Freq_{new} (in S102).

After the frequency determiner 907 determines that a first standby time elapsed (in S103), the frequency determiner 907 determines whether or not the temperature Tⱼ detected by the temperature sensor 901 is equal to or lower than the temperature threshold Tₜₕ (in S104). If the frequency determiner 907 determines that the detected temperature Tⱼ is equal to or lower than the temperature threshold Tₜₕ (YES in S104), the process returns to S101. If the frequency determiner 907 determines that the detected temperature Tⱼ is higher than the temperature threshold Tₜₕ (NO in S104), the frequency determiner 907 determines whether or not the temperature Tⱼ detected by the temperature sensor 901 continuously exceeds the temperature threshold Tₜₕ for a predetermined time period (in S105). If the frequency determiner 907 determines that the detected temperature Tⱼ does not continuously exceed the temperature threshold Tₜₕ for the predetermined time period (NO in S105), the process returns to S103. If the frequency determiner 907 determines that the detected temperature Tⱼ continuously exceeds the temperature threshold Tₜₕ for the predetermined time period (YES in S105), the frequency determiner 907 outputs, to the PLL controller 908, the frequency change instruction signal indicating an instruction to forcibly significantly reduce the oscillation frequency of the PLL 909 (in S106). Then, the process returns to S101.

If the frequency determiner 907 determines that the detected temperature Tⱼ is equal to or lower than the temperature threshold Tₜₕ (NO in S101), the frequency determiner 907 determines whether or not the oscillation frequency of the PLL 909 is the maximum frequency of the PLL 909 (in S107). If the frequency determiner 907 determines that the oscillation frequency of the PLL 909 is not the maximum frequency (NO in S107), the frequency determiner 907 outputs, to the PLL controller 908, the frequency change instruction signal indicating an instruction to increase the oscillation frequency of the PLL 909 by one level (in S108). Then, after the frequency determiner 907 determines that a second standby time elapsed (in S109), the process returns to S101.

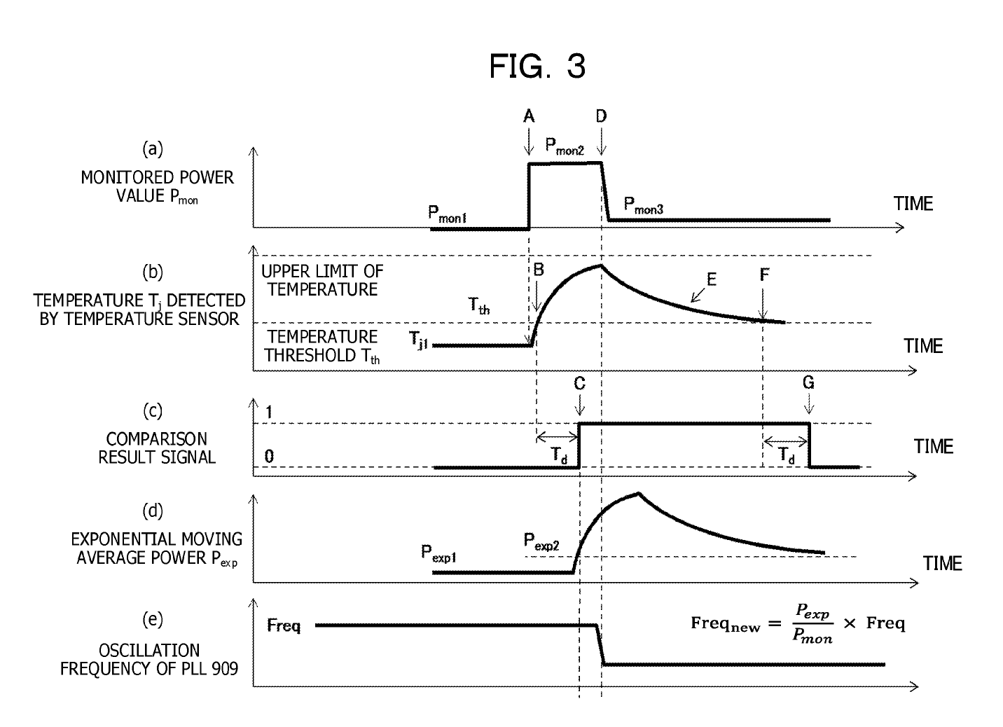

FIG. 3 is a diagram illustrating timing charts when the frequency determiner 907 executes the processes of S101 and S102 based on a change in the monitored power value Pₘₒₙ. In FIG. 3, (a) indicates a timing chart of the monitored power value Pₘₒₙ, (b) indicates a timing chart of the detected temperature Tⱼ, (c) indicates a timing chart of the comparison result signal, (d) indicates a timing chart of the exponential moving average power value Pₑᵣₚ, and (e) indicates a timing chart of the oscillation frequency of the PLL 909.

First, power consumed by the circuit section 911 and monitored by the power monitor 904 increases from a monitored power value Pₘₒₙ₁ to a monitored power value Pₘₒₙ₂ due to a change in operation of the circuit section 911 at a time indicated by an arrow A. In response to the increase in the power consumed by the circuit section 911 from the monitored power value Pₘₒₙ₁ to the monitored power value Pₘₒₙ₂, the detected temperature Tⱼ gradually increases at a change rate based on the thermal time constant τ of the semiconductor device 900 from a detected temperature Tⱼ₁. Then, at a time indicated by an arrow B, the detected temperature Tⱼ reaches the temperature threshold Tₜₕ.

The frequency determiner 907 receives the comparison result signal indicating the signal value “1” at a time indicated by an arrow C when a predetermined delay time T_{d} caused by the presence of the elements including the AD converter 902 elapses after the time indicated by the arrow B.

In response to the reception of the comparison result signal indicating the signal value “1”, the frequency determiner 907 outputs a change request signal indicating a request to change the oscillation frequency of the PLL 909 from the current frequency Freq to the change frequency Freq_{new}. The change frequency Freq_{new} is calculated by the frequency calculator 906 based on the consumed power value Pₘₒₙ₂ of the circuit section 911 after the increase, the exponential moving average power value Pₑₓₚ upon the change in the signal value of the comparison result signal from “0” to “1”, and the current frequency Freq of the PLL 909. The exponential moving average power value Pₑₓₚ is output after being delayed for the time period from the time when the temperature sensor 901 detects the temperature Tⱼ to the time when the comparison result signal is input to the frequency determiner 907. Thus, the exponential moving average power value Pₑₓₚ indicates power corresponding to a change in the temperature of the circuit section 911.

Then, at a time indicated by an arrow D, the oscillation frequency of the PLL 909 is changed from the frequency Freq to the change frequency Freq_{new}, and the power consumed by the circuit section 911 and monitored by the power monitor 904 is reduced from the monitored power value Pₘₒₙ₂ to a monitored power value Pₘₒₙ₃ due to the change in the oscillation frequency. Due to the reduction in the power consumed by the circuit section 911 from the monitored power value Pₘₒₙ₂ to the monitored power value Pₘₒₙ₃, the detected temperature Tⱼ is gradually reduced as indicated by an arrow E. Then, the detected temperature Tⱼ is reduced to the temperature threshold Tₜₕ at a time indicated by an arrow F. Then, the frequency determiner 907 receives the comparison result signal indicating the signal value “0” at a time indicated by an arrow G when a predetermined delay time T_{d} elapses after the reduction in the detected temperature Tⱼ to the temperature threshold Tₜₕ.

Effects of Related Semiconductor Device

The semiconductor device 900 controls the operational frequency of the PLL 909 while treating, as a power value that becomes stable when the temperature of the circuit 911 is equal to the temperature threshold Tₜₕ, the exponential moving average power value Pₑₓₚ that corresponds to a change in the temperature of the circuit section 911 when the temperature of the circuit section 911 reaches the temperature threshold Tₜₕ. Specifically, the semiconductor device 900 reduces the operational frequency of the PLL 909 based on the ratio of the exponential moving average power value Pₑₓₚ to the consumed power value Pₘₒₙ of the circuit section 911 and may stably maintain the value Pₘₒₙ of power consumed by the circuit section 911 at the power value that becomes stable when the temperature of the circuit 911 is equal to the temperature threshold Tₜₕ.

Since the semiconductor device 900 controls the operational frequency of the PLL 909 based on the temperature, measured by the temperature sensor 901, of the circuit section 911, instead of controlling the operational frequency based on a temperature estimated from power, error margins such as margins obtained by the estimation of a peripheral temperature and power temperature conversion based on a cooling system are not considered. Since the error margins such as a margin obtained by the use of a temperature estimated from power are not considered in the semiconductor device 900, the semiconductor device 900 may achieve high-accuracy control.

Since the time constant τ of the exponential moving average filter 905 is defined to correspond to the thermal time constant of the semiconductor device 900, the exponential moving average power value Pₑₓₚ calculated by the exponential moving average filter 905 corresponds to the detected temperature Tⱼ. Since the semiconductor device 900 treats, as target power, the exponential moving average power value Pₑₓₚ corresponding to the detected temperature Tⱼ, the semiconductor device 900 may adjust the temperature of the circuit section 911 so that the temperature of the circuit section 911 matches the temperature threshold.

Problem with Related Semiconductor Device

However, since the semiconductor device 900 uses the temperature Tⱼ detected by the temperature sensor 901, the operational frequency of the PLL 909 is not controlled until the predetermined delay time T_{d} elapses after the reduction in the detected temperature Tⱼ to the temperature threshold Tₜₕ. Since the temperature of the circuit section 911 increases during the delay time T_{d} from the time when the temperature sensor 901 detects the temperature Tⱼ to the time when operational frequency of the PLL 909 is changed, the temperature threshold Tₜₕ is reduced by the value of the increase in the temperature during the delay time T_{d} and set, compared with the upper limit of the temperature.

If the temperature sensor 901 is installed outside the semiconductor device 900 or is an off-chip temperature sensor, the delay time T_{d} may be several milliseconds or longer depending on a delay caused by an element of the temperature sensor 901, a delay caused by a wiring between the temperature sensor 901 and the semiconductor device 900, and the like. A time period for calculating the monitored power value by the power monitor 904 is much shorter than the delay time T_{d} and is approximately several hundreds of microseconds.

Configuration and Functions of Semiconductor Device According to Embodiment

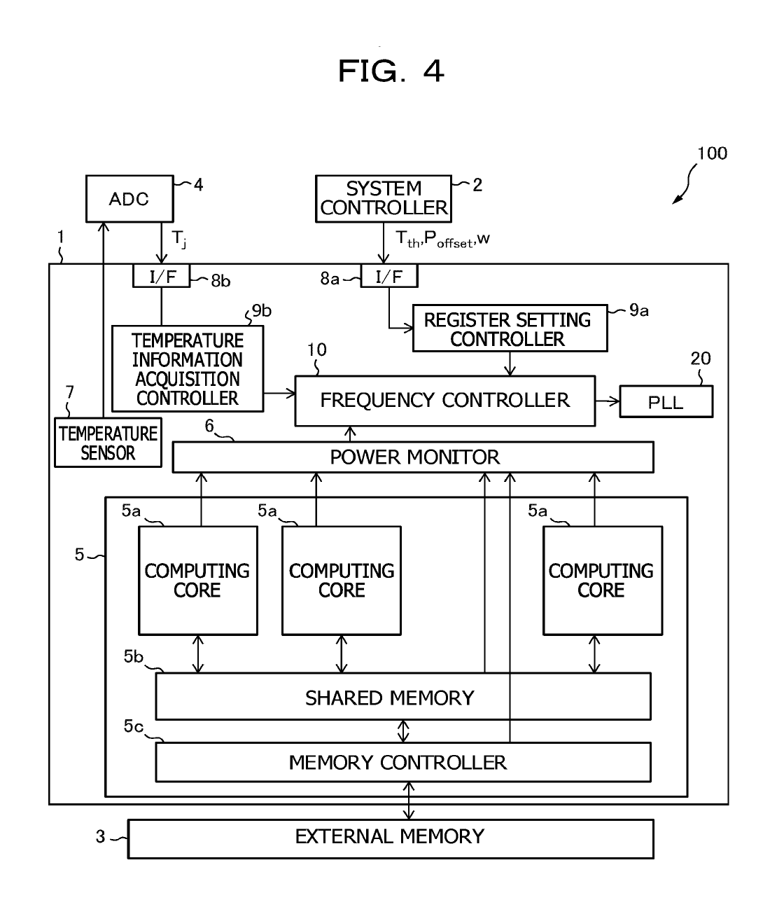

FIG. 4 is a block diagram of an electronic device including the semiconductor device according to the embodiment.

The electronic device 100 includes the semiconductor device 1, a system controller 2, an external memory 3, and an analog-to-digital converter (ADC) 4. The semiconductor device 1 includes a circuit section 5, a power monitor 6, a temperature sensor 7, a first interface section 8a, a second interface section 8b, a register setting controller 9a, a temperature information acquisition controller 9b, a frequency controller 10, and a PLL 20.

The semiconductor device 1 is, for example, a processor (CPU) and is requested to operate so that power consumed by the semiconductor device 1 and the temperature of the semiconductor device 1 do not exceed an upper limit of consumed power and an upper limit of the temperature. The system controller 2 is a high-level control device that controls the various devices installed in the electronic device 100 including the semiconductor device 1. The system controller 2 outputs, to the semiconductor device 1, a temperature threshold signal indicating a temperature threshold Tₜₕ, a weight coefficient signal indicating a weight coefficient w, and an offset power signal indicating an offset power value P_{offset}. The temperature threshold Tₜₕ is able to be set by an operator (not illustrated) so that even when power consumed by the circuit section 5 reaches the maximum power amount due to a change in operation of the circuit section 5, the temperature of the semiconductor device 1 does not exceed the upper limit of the temperature of the semiconductor device 1. The weight coefficient w is used by the frequency controller 10 for calculation. The offset power value P_{offset} is P a fixed value to be used by the frequency controller 10 for calculation. The external memory 3 is a storage device installed outside the semiconductor device 1 and is a random access memory (RAM), a read only memory (ROM), or the like. The AD converter 4 converts a temperature signal received from the temperature sensor 7 from an analog signal to a digital signal and outputs the digital signal to the semiconductor device 1. The circuit section 5 includes a plurality of computing cores 5a, a shared cache 5b, and a memory controller 5c. The computing cores 5a execute predetermined processes based on a computer program stored in the shared cache 5b and data. The shared cache 5b is a storage region accessible from the computing cores 5a. The memory controller 5c causes information, stored in the external memory 3, of various types to be stored in the shared cache 5b.

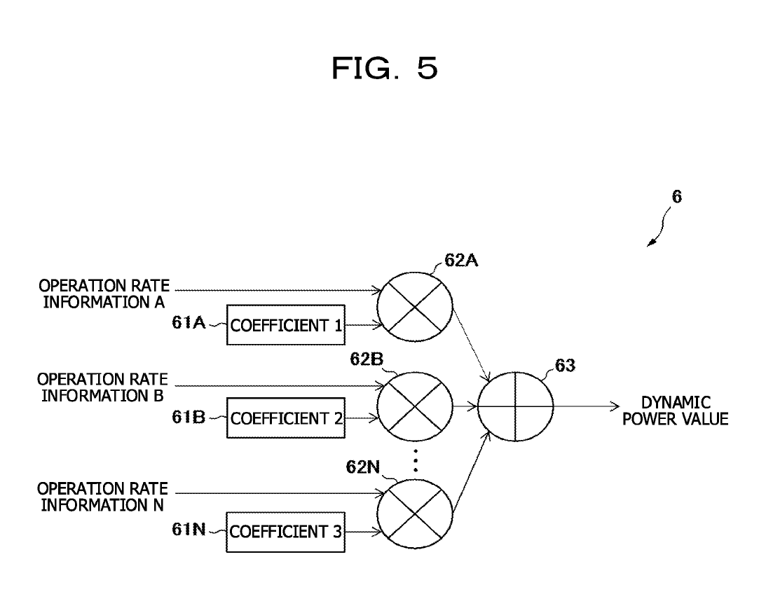

FIG. 5 is a diagram illustrating an example of an internal circuit of the power monitor 6.

The power monitor 6 includes a plurality (number N in this example) of monitor registers 61A to 61N, a plurality of monitor multipliers 62A to 62N, and a monitor adder 63 and acquires, as a monitored power value Pₘₒₙ, power consumed by the circuit section 5. The power monitor 6 acquires operation rate information A to N of signals having high correlations with power consumed by the plurality of computing cores 5a, the shared cache 5b, and the memory controller 5c. The power monitor 6 uses the monitor multipliers 62A to 62N to multiply the operation rate information A to N by appropriate weight coefficients stored in the monitor registers 61A to 61N and uses the monitor adder 63 to sum values obtained by multiplying the operation rate information A to N by the weight coefficients. The total of the values corresponds to or nearly corresponds to a dynamic power value of the circuit section 5. The power monitor 6 outputs a monitored power value signal indicating the calculated monitored power value Pₘₒₙ to the frequency controller 10.

The temperature sensor 7 is an on-chip temperature sensor. As an example, the temperature sensor 7 is a bandgap temperature sensor. The temperature sensor 7 detects the temperature of the circuit section 5 and outputs a temperature signal indicating the detected temperature to the AD converter 4.

The first interface section 8a and the second interface section 8b are input and output (I/O) cells that connect an internal circuit of the semiconductor device 1 to the externals of the semiconductor device 1. The first interface section 8a outputs, to the register setting controller 9a, the temperature threshold signal received from the system controller 2, the weight coefficient signal received from the system controller 2, and the offset power signal received from the system controller 2. The second interface section 8b outputs, to the temperature information acquisition controller 9b, the temperature signal received from the AD converter 4.

The register setting controller 9a writes, in registers of the frequency controller 10, the temperature threshold Tₜₕ corresponding to the temperature threshold signal received from the system controller 2, the weight coefficient w corresponding to the weight coefficient signal received from the system controller 2, and the offset power value P_{offset} corresponding to the offset power signal received from the system controller 2. The temperature information acquisition controller 9b outputs, to the frequency controller 10, the temperature signal indicating the detected temperature Tⱼ and received from the AD converter 4.

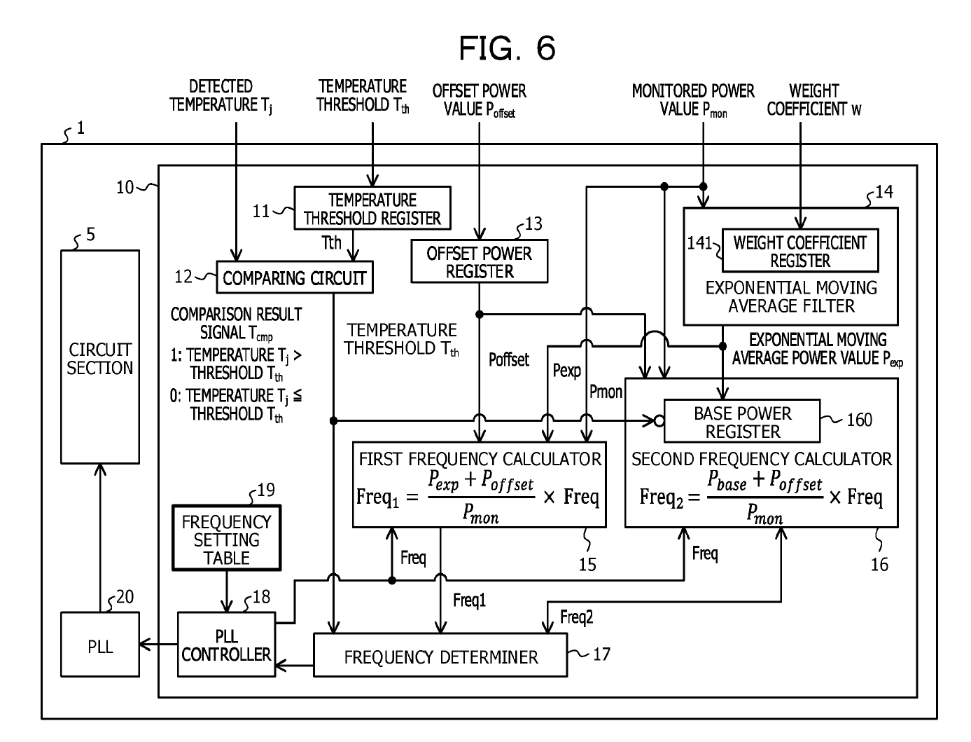

FIG. 6 is an internal circuit block diagram of the frequency controller 10.

The frequency controller 10 includes a temperature threshold register 11, a comparing circuit 12, an offset power register 13, an exponential moving average filter 14, a first frequency calculator 15, a second frequency calculator 16, and a frequency determiner 17. The frequency controller 10 further includes a PLL controller 18 and a frequency setting table 19.

The frequency threshold register 11 stores the temperature threshold Tₜₕ received from the system controller 2 via the register setting controller 9a and outputs the stored temperature threshold Tₜₕ to the comparing circuit 12. The temperature threshold Tₜₕ is set so that even when the temperature of the semiconductor device 1 changes at the maximum change rate and exceeds temperature threshold Tₜₕ, the temperature of the semiconductor device 1 does not exceed an operation-guaranteed upper limit temperature. Specifically, the temperature threshold Tₜₕ is calculated as Tₜₕ=Tₗᵢₘᵢₜ−ΔT1−T_{margin} from the operation-guaranteed upper limit temperature Tₗᵢₘᵢₜ, a first temperature increase rate ΔT1, and a margin temperature T_{margin} that is a temperature corresponding to a control margin. The operation-guaranteed upper limit temperature Tₗᵢₘᵢₜ is determined based on a temperature condition upon timing design and the like. The first temperature increase rate ΔT1 is the value of an increase in the temperature of the circuit section 5 from the temperature threshold Tₜₕ upon an estimated maximum change in power at an estimated maximum change rate during a control time period D1 from the time when the temperature of the circuit section 5 exceeds the temperature threshold Tₜₕ to the time when the frequency of the PLL 20 is reduced in response to a change in the output of the temperature sensor 7.

The comparing circuit 12 compares the temperature Tⱼ detected by the temperature sensor 7 with the temperature threshold Tₜₕ. The comparing circuit 12 outputs, to the second frequency calculator 16 and the frequency determiner 17, a comparison result signal T_{cmp} indicating a signal value “1” when the detected temperature Tⱼ corresponding to the temperature signal is higher than the temperature threshold Tₜₕ. In addition, the comparing circuit 12 outputs, to the second frequency calculator 16 and the frequency determiner 17, the comparison result signal T_{cmp} indicating a signal value “0” when the detected temperature Tⱼ corresponding to the temperature signal is equal to or lower than the temperature threshold Tₜₕ.

The offset power register 13 stores the offset power value P_{offset} received from the system controller 2 via the register setting controller 9a and outputs the stored offset power value P_{offset} to the first frequency calculator 15 and the second frequency calculator 16.

The exponential moving average filter 14 includes a weight coefficient register 141. The exponential moving average filter 14 calculates an exponential moving average or one of moving averages and outputs an exponential moving average signal indicating the calculated exponential moving average power value Pₑₓₚ to the first frequency calculator 15 and the second frequency calculator 16.

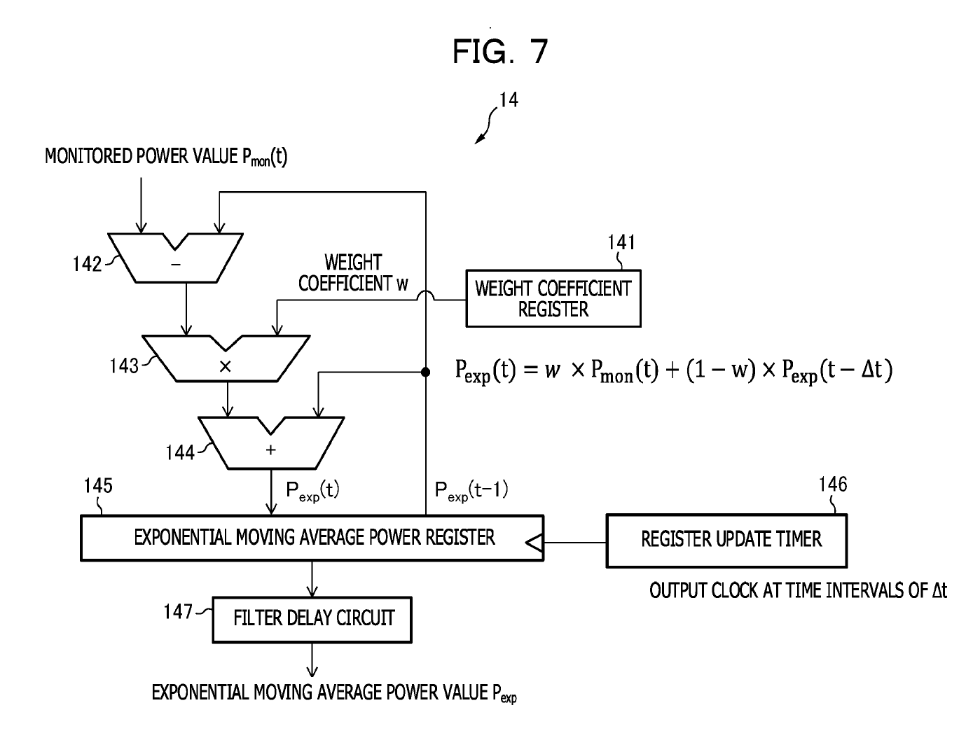

FIG. 7 is an internal circuit block diagram of the exponential moving average filter 14.

The exponential moving average filter 14 includes the weight coefficient register 141, a filter subtractor 142, a second filter multiplier 143, and a filter adder 144. The exponential moving average filter 14 further includes a moving average power register 145, a register update timer 146, and a filter delay circuit 147. The exponential moving average filter 14 functions as a power estimator that estimates, based on the monitored power value Pₘₒₙ, a base power value P_{base} corresponding to the temperature of the circuit section 5 when the temperature detected by the temperature sensor 7 matches the temperature threshold Tₜₕ.

The filter subtractor 142, the second filter multiplier 143, and the filter adder 144 calculate a current exponential moving average power value Pₑₓₚ(t) from a previous exponential moving average power value Pₑₓₚ(t−Δt), a current monitored power value Pₘₒₙ(t), and the weight coefficient w. The exponential moving average power value Pₑₓₚ(t) is expressed by Equation (2).

Pₑₓₚ(t)=w×Pₘₒₙ(t)+(1−w)×Pₑₓₚ(t−Δt) (2)

The moving average power register 145 stores the calculated exponential moving average power value Pₑₓₚ. The register update timer 146 outputs a clock signal to the moving average power register 145 at time intervals of Δt and updates the exponential moving average power value Pₑₓₚ stored in the moving average power register 145. The filter delay circuit 147 includes flip-flops connected in series and outputs the exponential moving average power value Pₑₓₚ after delaying the exponential moving average power value Pₑₓₚ for a delay time corresponding to a time period from the time when the temperature sensor 7 detects the temperature Tⱼ to the time when the comparison result signal T_{cmp} is input to the frequency determiner 17.

The weight coefficient w is determined so that the exponential moving average power value Pₑₓₚ changes in synchronization with a change in the temperature of the circuit section 5. When the temperature Ta of air outside the semiconductor device 1 is maintained at a fixed value, the current temperature T(t) of the semiconductor device 1 is expressed by Equation (3).

$$T ( t ) = Δ t \times \frac{{P}_{mon} ( t )}{C} - ( 1 - Δ t / τ ) \times T ( t - Δ t ) \qquad ( 3 )$$

In Equation (3), Δt indicates time change, and α is expressed by α=Δt/(Cθ), where C is the heat capacity of the semiconductor device 1 and θ is the thermal resistance of the semiconductor device 1. The exponential moving average power value Pₑₓₚ(t) and the temperature T(t) have a relation of (Pₑₓₚ(t)=T(t)/θ). Thus, by controlling the exponential moving average power value Pₑₓₚ(t) to a predetermined value, the temperature T(t) of the circuit section 5 may be controlled to a desired temperature.

The first frequency calculator 15 calculates a first frequency Freq₁ based on the monitored power value Pₘₒₙ received from the power monitor 6, the exponential moving average power value Pₑₓₚ received from the exponential moving average filter 14, the offset power value P_{offset} received from the offset power register 13, and the current frequency Freq. The first frequency Freq₁ is expressed by Equation (4).

$${Freq}_{1} = \frac{{P}_{exp} + {P}_{offset}}{{P}_{mon}} \times Freq \qquad ( 4 )$$

The second frequency calculator 16 includes a base power register 160 and calculates a second frequency Freq₂. The base power register 160 stores, as the base power value P_{base}, the exponential moving average power value Pₑₓₚ received from the exponential moving average filter 14 when the signal value of the comparison result signal T_{cmp} is “1”. The second frequency Freq₂ is expressed by Equation (5) based on the monitored power value Pₘₒₙ received from the power monitor 6, the exponential moving average power value P_{base} stored in the base power register 160, the offset power value P_{offset} received from the offset power register, and the current frequency Freq.

$${Freq}_{2} = \frac{{P}_{base} + {P}_{offset}}{{P}_{mon}} \times Freq \qquad ( 5 )$$

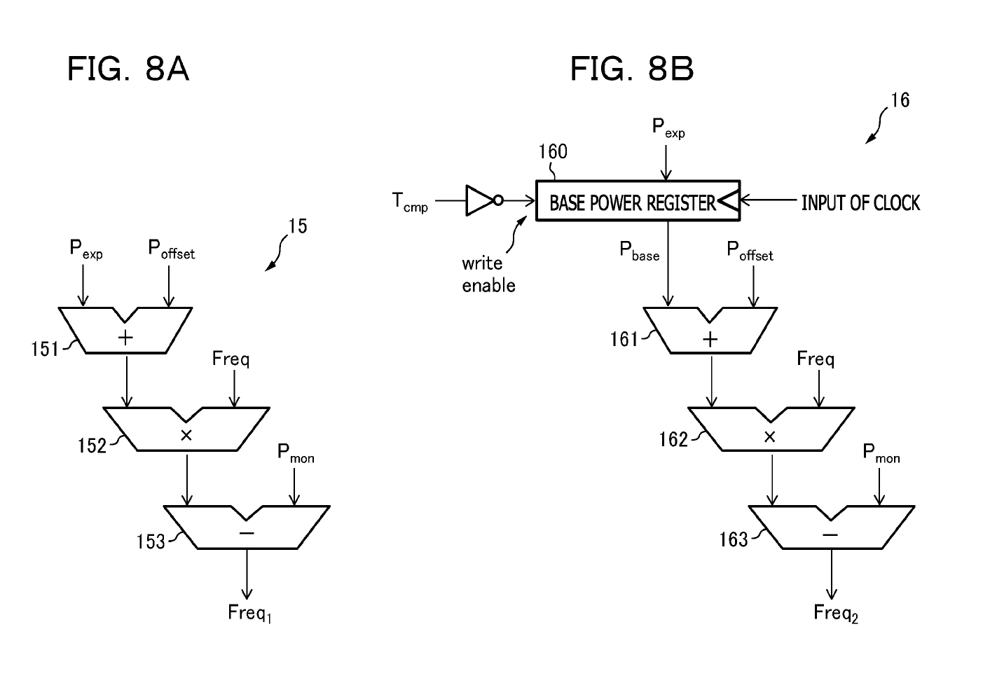

FIG. 8A is an internal circuit block diagram of the first frequency calculator 15, and FIG. 8B is an internal circuit block diagram of the second frequency calculator 16.

The first frequency calculator 15 includes a first calculation adder 151, a first calculation multiplier 152, and a first calculation subtractor 153. The first calculation adder 151 sums the exponential moving average power value Pₑₓₚ and the offset power value P_{offset}. The first calculation multiplier 152 multiplies the output of the first calculation adder 151 by the current frequency Freq. The first calculation subtractor 153 subtracts the monitored power value Pₘₒₙ from the output of the first calculation multiplier 152 and outputs the first frequency Freq₁.

The second frequency calculator 16 includes the base power register 160, a second calculation adder 161, a second calculation multiplier 162, and a second calculation subtractor 163. The base power register 160 stores, as the base power value P_{base}, the exponential moving average power value Pₑₓₚ received from the exponential moving average filter 14 when the signal value of the comparison result signal T_{cmp} is “1”. The second calculation adder 161 sums the base power value P_{base} and the offset power value P_{offset}. The second calculation multiplier 162 multiplies the output of the second calculation adder 161 by the current frequency Freq. The second calculation subtractor 163 subtracts the monitored power value Pₘₒₙ from the output of the second calculation multiplier 162 and outputs the second frequency Freq₂.

The offset power value P_{offset} is a reduced amount of a threshold margin due to a reduction in a control delay caused by switching from control executed based on the temperature Tⱼ detected by the temperature sensor 7 to control executed based on the monitored power value Pₘₒₙ calculated by the power monitor 6. The offset power value P_{offset} is calculated as P_{offset}=(ΔT1−ΔT2)/θc−P_{margin}, where the first temperature increase rate ΔT1 is the value of the increase in the temperature of the circuit section 5 from the temperature threshold Tₜₕ upon the estimated maximum increase in the power at the estimated maximum change rate during the control time period D1 from the time when the temperature of the circuit section 5 exceeds the temperature threshold Tₜₕ to the time when the frequency is reduced in response to the change in the output of the temperature sensor 7, a second temperature increase rate ΔT2 is the maximum value of an increase in the temperature of the semiconductor device 1 upon an estimated maximum increase in power at an estimated maximum change rate during a control time period D2 from the time when the power increases to the time when the frequency is reduced in response to the output of the power monitor 6. The thermal resistance θc of the semiconductor device 1 is a thermal resistance component contributing to a change in the temperature at a high rate for a time period of several milliseconds to several tens of milliseconds. As an example, the thermal resistance θc of the semiconductor device 1 is the thermal resistance of a chip of the semiconductor device 1. As another example, the thermal resistance θc of the semiconductor device 1 is the thermal resistance of a thermal interface material (TIM) between the chip and a package of the semiconductor device 1.

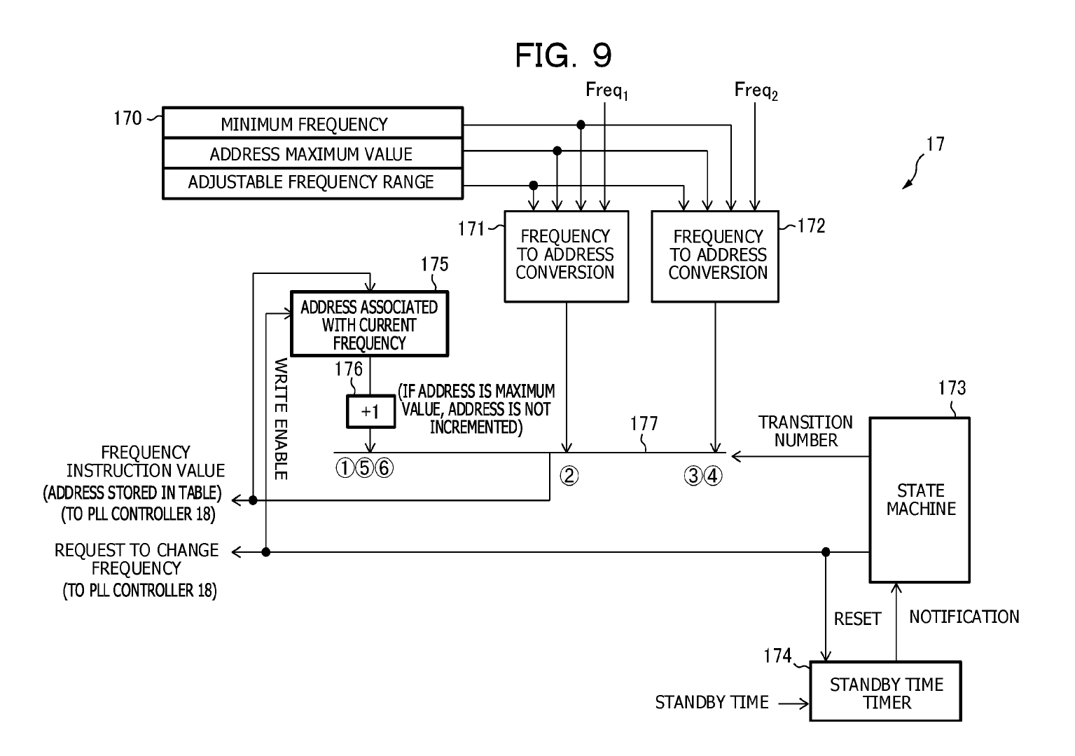

FIG. 9 is a diagram illustrating an example of an internal configuration of the frequency determiner 17.

The frequency determiner 17 includes a control register 170, a first converter 171, a second converter 172, a state machine 173, a standby time timer 174, an address register 175, an address incrementing section 176, and a control selector 177. The frequency determiner 17 determines the frequency of a clock (hereinafter also referred to as clock signal) so that power consumed by the circuit section 5 matches target power that causes the temperature of the circuit section 5 to converge to a temperature higher than the temperature threshold Tₜₕ when the temperature detected by the temperature sensor 7 exceeds the temperature threshold Tₜₕ. Specifically, the frequency determiner 17 determines the frequency of the clock to be output from the PLL 20 so that the monitored power value Pₘₒₙ matches the target power when the temperature detected by the temperature sensor 7 exceeds the temperature threshold Tₜₕ. More specifically, when the temperature of the chip exceeds the threshold, P_{base}<Pₘₒₙ<Pₘₒₙ+P_{offset} is established, the frequency does not reach an upper limit of the frequency, and the output of the temperature sensor becomes 1, the frequency is adjusted and increased so that Pₘₒₙ matches P_{base}+P_{offset}. In addition, the target power is a power value obtained by adding the base power to the offset power and is equal to P_{base}+(ΔT1−ΔT2)/θc−P_{margin}.

The control register 170 stores the lowest frequency of the PLL 20, the maximum value among addresses stored in the frequency setting table 19, and an adjustable frequency range. The first converter 171 calculates an address associated with a set frequency value that is not higher than and is closest to the first frequency Freq₁ from a formula of ((the first frequency Freq₁−the lowest frequency)/(the adjustable frequency range)) based on the first frequency Freq₁, the lowest frequency stored in the control register 170, and the adjustable frequency range stored in the control register 170. Then, the first converter 171 outputs the calculated address. If the calculated address exceeds the maximum value among the addresses, the control register 170 outputs the maximum value among the addresses. The second converter 172 calculates an address associated with a set frequency value that is not higher than and is closest to the second frequency Freq₂ from a formula of ((the second frequency Freq₂−the lowest frequency)/(the adjustable frequency range)) based on the second frequency Freq₂, the lowest frequency stored in the control register 170, and the adjustable frequency range stored in the control register 170. Then, the second converter 172 outputs the calculated address. If the calculated address exceeds the maximum value among the addresses, the control register 170 outputs the maximum value among the addresses.

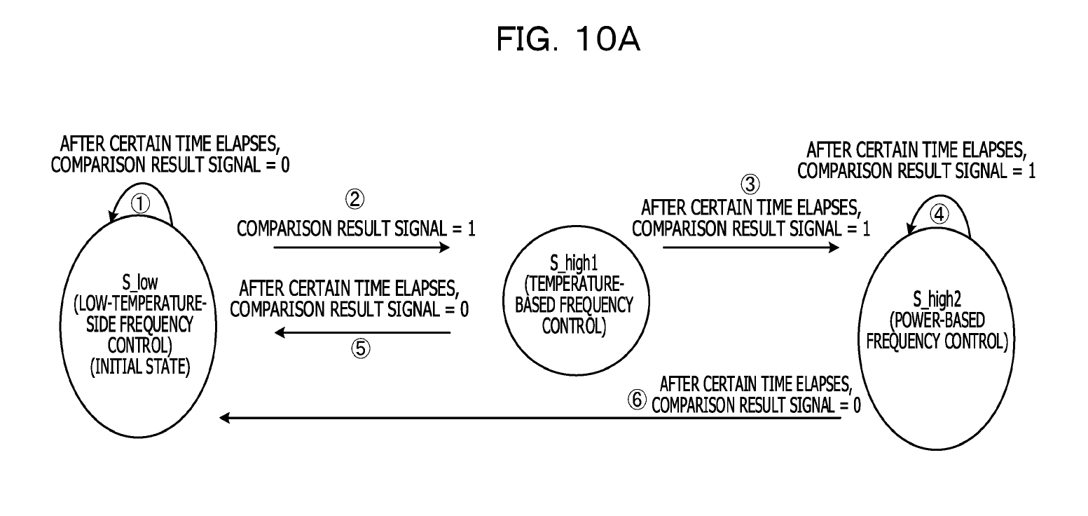

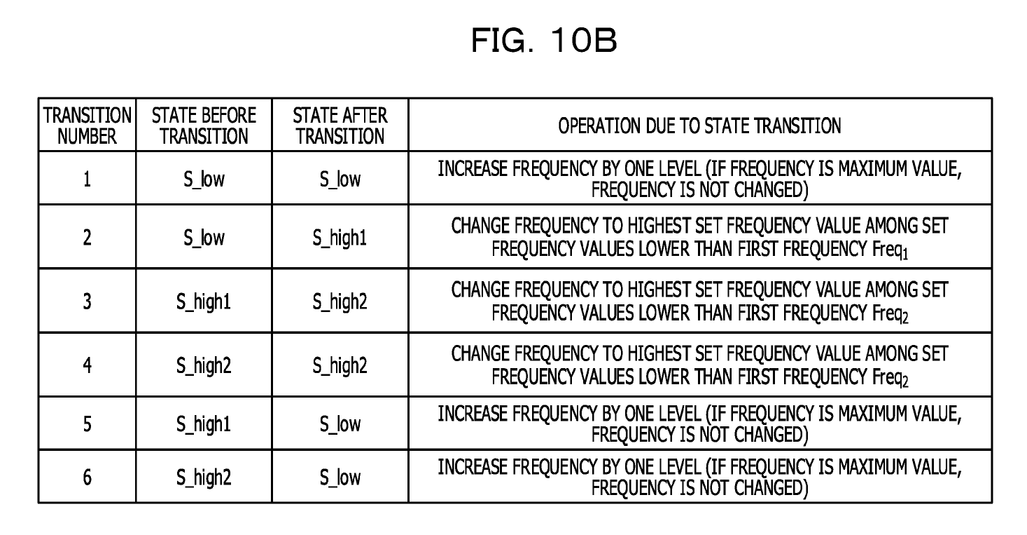

FIG. 10A is a diagram illustrating an internal configuration of the state machine 173. FIG. 10B is a diagram describing transitions between states of the state machine 173.

The state machine 173 transitions from a certain state to another state in response to the reception of a notification signal from the standby time timer 174. When transitioning from a certain state to another state, the state machine 173 outputs, to the control selector 177, a transition number signal indicating a transition number after the state transition and outputs, to the standby time timer 174 and the PLL controller 18, a frequency change request signal indicating a request to change the frequency.

A transition number 1 indicates a transition when the temperature Tⱼ detected by the temperature sensor 7 becomes equal to or lower than the temperature threshold Tₜₕ after a certain time elapses from a state in which the detected temperature Tⱼ is equal to or lower than the temperature threshold Tₜₕ. In the transition indicated by the transition number 1, the state machine 173 increases the current frequency Freq by one level. If the current frequency Freq is equal to the maximum adjustable frequency of the PLL 20, the state machine 173 does not change the current frequency Freq.

A transition number 2 indicates a transition when the detected temperature Tⱼ becomes higher than the temperature threshold Tₜₕ from a state in which the detected temperature Tⱼ is equal to or lower than the temperature threshold Tₜₕ. In the transition indicated by the transition number 2, the state machine 173 changes the frequency to the highest set frequency value among set frequency values lower than the first frequency Freq₁.

A transition number 3 indicates a transition when the detected temperature Tⱼ becomes higher than the temperature threshold Tₜₕ after a certain time elapses from a state in which the detected temperature Tⱼ is higher than the temperature threshold Tₜₕ. In the transition indicated by the transition number 3, the state machine 173 changes the frequency to the highest set frequency value among set frequency values lower than the first frequency Freq₂.

A transition number 4 indicates a transition when the detected temperature Tⱼ is continuously higher than the temperature threshold Tₜₕ after the transition indicated by the transition number 3. In the transition indicated by the transition number 4, the state machine 173 changes the frequency to the highest set frequency value among the set frequency values lower than the first frequency Freq₂ in the same manner as the change upon the transition indicated by the transition number 3.

A transition number 5 indicates a transition when the detected temperature Tⱼ becomes equal to or lower than the temperature threshold Tₜₕ after the transition indicated by the transition number 2. In the transition indicated by the transition number 5, the state machine 173 increases the current frequency Freq by one level. If the current frequency Freq is equal to the maximum adjustable frequency of the PLL 20, the state machine 173 does not change the current frequency Freq.

A transition number 6 indicates a transition when the detected temperature Tⱼ becomes equal to or lower than the temperature threshold Tₜₕ after the transition indicated by the transition number 3 or 4. In the transition indicated by the transition number 6, the state machine 173 increases the current frequency Freq by one level. If the current frequency Freq is equal to the maximum adjustable frequency of the PLL 20, the state machine 173 does not change the current frequency Freq.

The standby time timer 174 counts time elapsed after the frequency change request signal is received by the standby time timer 174 from the state machine 173. The standby time timer 174 outputs the notification signal to the state machine 173 when a predetermined standby time elapses after the reception of the frequency change request signal from the state machine 173.

The address register 175 stores an address associated with the current frequency Freq. When the address stored in the address register 175 is not the maximum value among the addresses, the address incrementing section 176 increments the address stored in the address register 175 and outputs the incremented address. When the address stored in the address register 175 is the maximum value among the addresses, the address incrementing section 176 outputs the address stored in the address register 175.

The control selector 177 outputs a frequency instruction signal indicating a frequency instruction value that is an address selected based on a transition number corresponding to a transition number signal received from the state machine 173. Upon each of the transitions indicated by the transition numbers 1, 5, and 6 corresponding to transition number signals, the control selector 177 outputs the frequency instruction signal indicating an address received from the address incrementing section 176. Upon the transition indicated by the transition number 2 corresponding to a transition number signal, the control selector 177 outputs the frequency instruction signal indicating an address received from the first converter 171. Upon each of the transitions indicated by the transition numbers 3 and 4 corresponding to transition number signals, the control selector 177 outputs the frequency instruction signal indicating an address received from the first converter 171.

The PLL controller 18 references the frequency setting table 19 and sets the frequency of the PLL 20 based on the frequency instruction signal received from the frequency determiner 17 and the frequency change request signal received from the frequency determiner 17. A table 1 is an example of the frequency setting table 19.

TABLE 1

| Address | PLL Frequency Setting | Frequency (MHz) |
|---|---|---|
| 0 | 0x304 | 2000 |
| 1 | 0x028 | 2050 |
| 2 | 0x114 | 2100 |
| | — | — |
| 56 | 0x12e | 4700 |
| | — | — |
| 60 | 0x130 | 4900 |
| 61 | 0x062 | 4950 |
| 62 | 0x218 | 5000 |

The frequency setting table 19 stores addresses, PLL frequency settings, and set frequencies. The frequency setting table 19 stores the addresses and the set frequencies so that the frequencies=the lowest frequency+the addresses×the adjustable frequency range. As indicated in the table 1, the lowest frequency is 2000 MHz and the adjustable frequency range is 50 MHz.

The PLL 20 oscillates at a frequency based on control by the PLL controller 18 to generate the clock signal and outputs the generated clock signal to the circuit section 5.

Operations of Semiconductor Device According to Embodiment

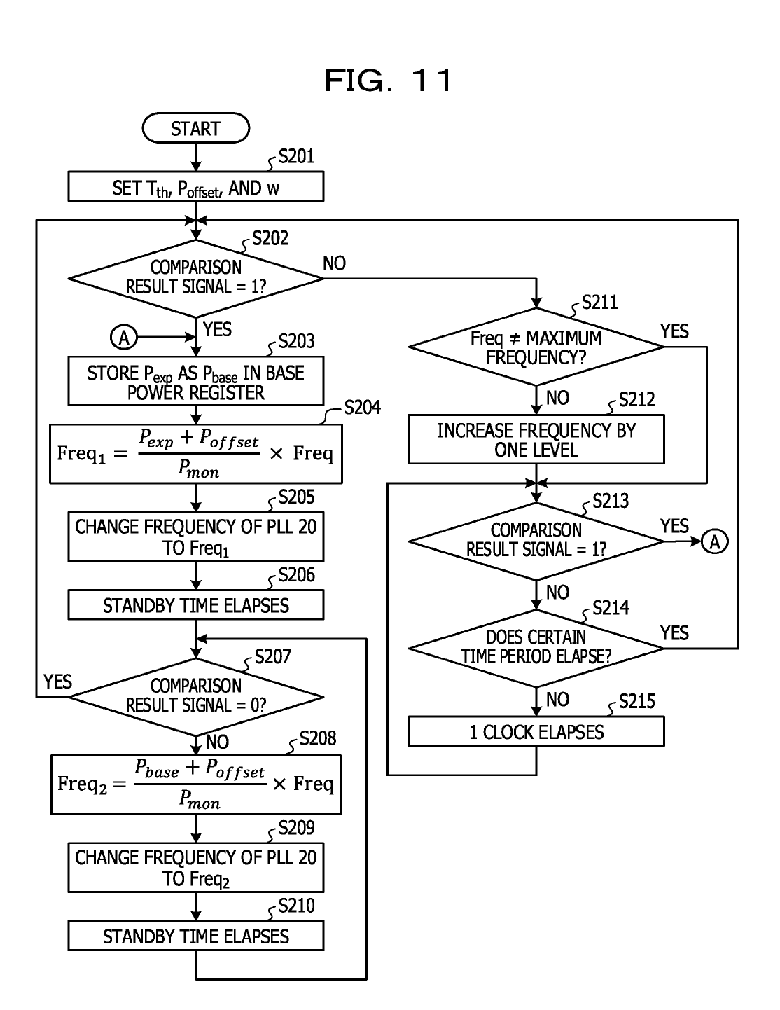

FIG. 11 is a flowchart of a frequency control process to be executed by the semiconductor device 1.

The system controller 2 sets the temperature threshold Tₜₕ, the offset power value P_{offset}, and the weight coefficient w in the registers of the frequency controller 10 via the register setting controller 9a (in S201). Specifically, the temperature threshold Tₜₕ is stored in the temperature threshold register 11, the offset power value P_{offset} is stored in the offset power register 13, and the weight coefficient w is stored in the weight coefficient register 141. Then, the frequency determiner 17 determines whether or not the signal value of the comparison result signal T_{cmp} received from the comparing circuit 12 is “1” (in S202). If the signal value of the comparison result signal T_{cmp} output from the comparing circuit 12 is “1”, the base power register 160 stores, as the base power value P_{base}, the exponential moving average power value Pₑᵣₚ received from the exponential moving average filter 14 (in S203). In addition, the first frequency calculator 15 calculates the first frequency Freq₁ according to Equation (4) (in S204). If the frequency determiner 17 determines that the signal value of the comparison result signal T_{cmp} output from the comparing circuit 12 is “1” (YES in S202), the frequency determiner 17 outputs, to the PLL controller 18, a frequency change instruction signal indicating an instruction to change the oscillation frequency of the PLL 20 to the first frequency Freq₁ (in S205). After the frequency determiner 17 determines that a predetermined standby time elapses (in S206), the frequency determiner 17 determines whether or not the signal value of the comparison result signal T_{cmp} received from the comparing circuit 12 is “0” (in S207).

The second frequency calculator 16 calculates the second frequency Freq₂ according to Equation (5) (in S208). If the frequency determiner 17 determines that the signal value of the comparison result signal Tcmp output from the comparing circuit 12 is “1” (NO in S207), the frequency determiner 17 outputs, to the PLL controller 18, the frequency change instruction signal indicating an instruction to change the oscillation frequency of the PLL 20 to the second frequency Freq₂ (in S209). After the frequency determiner 17 determines that a first standby time elapsed (in S210), the frequency determiner 17 determines whether or not the signal value of the comparison result signal T_{cmp} output from the comparing circuit 12 is “0” (in S207). Until the frequency determiner 17 determines that the signal value of the comparison result signal T_{cmp} output from the comparing circuit 12 is “0” (YES in S207), the processes of S207 to S210 are repeated. If the frequency determiner 17 determines that the signal value of the comparison result signal T_{cmp} output from the comparing circuit 12 is “0” (YES in S207), the process returns to S202.

If the frequency determiner 17 determines that the signal value of the comparison result signal T_{cmp} output from the comparing circuit 12 is “0” (NO in S202), the frequency determiner 17 determines whether or not the current frequency is the maximum frequency (in S211). If the frequency determiner 17 determines that the current frequency is not the maximum frequency (NO in S211), the frequency determiner 17 increments an address associated with the current frequency and increases the frequency by one level (in S212). Then, if the frequency determiner 17 determines that the signal value of the comparison result signal T_{cmp} output from the comparing circuit 12 is “1” (YES in S213), the process proceeds to S203. If the frequency determiner 17 determines that the signal value of the comparison result signal T_{cmp} output from the comparing circuit 12 is not “1” (NO in S213) until a certain time period elapses (in S214), the process returns to S202.

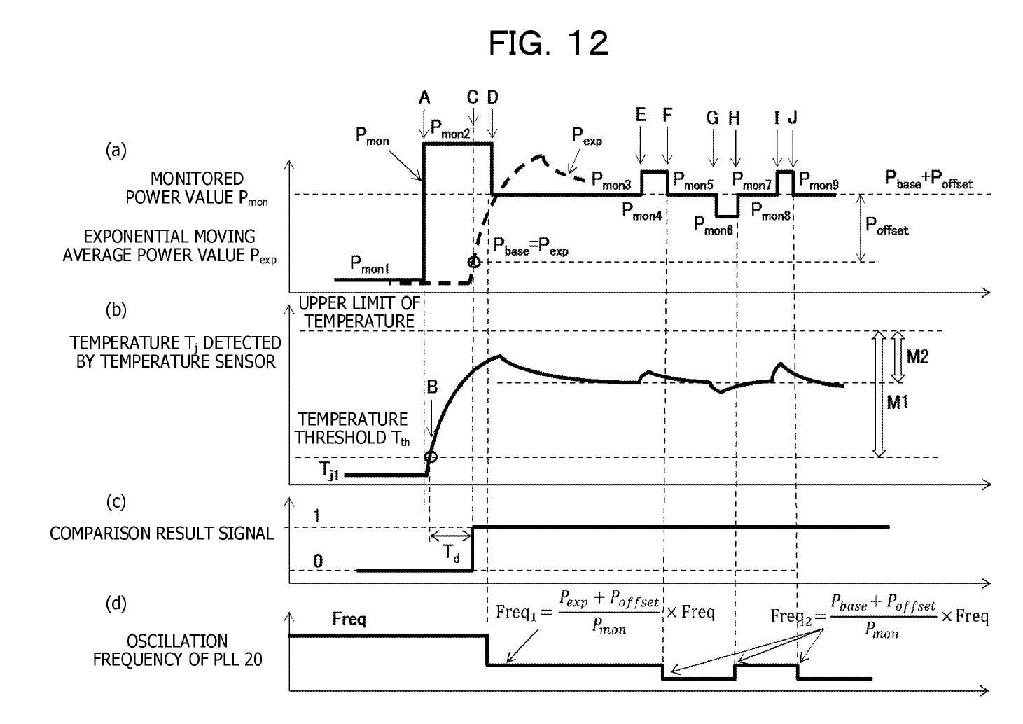

FIG. 12 is a diagram illustrating timing charts when the frequency controller 10 executes the processes of S202 to S210 based on a change in the monitored power value Pₘₒₙ. In FIG. 12, (a) indicates a timing chart of the monitored power value Pₘₒₙ and the exponential moving average power value Pₑₓₚ, (b) indicates a timing chart of the detected temperature Tⱼ, (c) indicates a timing chart of the comparison result signal, and (d) indicates a timing chart of the oscillation frequency of the PLL 20.

First, at a time indicated by an arrow A, power consumed by the circuit section 5 and monitored by the power monitor 6 increases from a monitored power value Pₘₒₙ₁ to a monitored power value Pₘₒₙ₂ due to a change in operation of the circuit section 5. In response to the increase in the power consumed by the circuit section 5 from the monitored power value Pₘₒₙ₁ to the monitored power value Pₘₒₙ₂, the detected temperature Tⱼ gradually increases at a change rate based on the thermal time constant τ of the semiconductor device 1. Then, at a time indicated by an arrow B, the detected temperature Tⱼ reaches the temperature threshold Tₜₕ.

The frequency controller 10 receives the comparison result signal indicating the signal value “1” at a time indicated by an arrow C when a predetermined delay time T_{d} caused by the presence of the elements including the AD converter 4 elapses after the time indicated by the arrow B. The base power register 160 stores, as the base power value P_{base}, the exponential moving average power value Pₑₓₚ received from the exponential moving average filter 14 in response to the reception of the comparison result signal T_{cmp} indicating the signal value “1”.

The frequency controller 10 outputs the frequency instruction signal indicating the instruction to change the oscillation frequency of the PLL 20 from the current frequency Freq to the first frequency Freq₁ in response to the reception of the comparison result signal indicating the signal value “1”. The first frequency Freq₁ is calculated by the frequency controller 10 from the consumed power value Pₘₒₙ₂ of the circuit section 5, the exponential moving average power value Pₑₓₚ upon the change in the signal value of the comparison result signal from “0” to “1”, the offset power value P_{offset}, and the current oscillation frequency Freq of the PLL 20. Since the filter delay circuit 147 outputs the exponential moving average power value Pₑₓₚ after delaying the exponential moving average power value Pₑₓₚ for a delay time corresponding to a time period from the time when the temperature sensor 7 detects the temperature Tⱼ to the time when the comparison result signal is input to the frequency controller 10, the exponential moving average power value Pₑₓₚ indicates power corresponding to a change in the temperature of the circuit section 5.

Then, at a time indicated by an arrow D, the oscillation frequency of the PLL 20 is changed from the frequency Freq to the first frequency Freq₁, and the power consumed by the circuit section 5 and monitored by the power monitor 6 is reduced from the monitored power value Pₘₒₙ₂ to a monitored power value Pₘₒₙ₃ due to the change in the oscillation frequency. The monitored power value Pₘₒₙ₃ is a value obtained by summing the base power value P_{base} and the offset power value P_{offset}.

Then, at a time indicated by an arrow E, the power consumed by the circuit section 5 and monitored by the power monitor 6 increases from the monitored power value Pₘₒₙ₃ to a monitored power value Pₘₒₙ₄ due to a change in operation of the circuit section 5. The frequency controller 10 determines that the signal value of the comparison result signal T_{cmp} is “1”, and the frequency controller 10 outputs, to the PLL controller 18, the frequency change instruction signal indicating the instruction to change the oscillation frequency of the PLL 20 to the second frequency Freq₂. Then, at a time indicated by an arrow F, the frequency of the PLL 20 is changed to the second frequency Freq₂, and the power consumed by the circuit section 5 is reduced to a monitored power value Pₘₒₙ₅ due to the change in the frequency. The monitored power value Pₘₒₙ₅ is a value obtained by summing the base power value P_{base} and the offset power value P_{offset}, like the monitored power value Pₘₒₙ₃.

Then, at a time indicated by an arrow G, the power consumed by the circuit section 5 and monitored by the power monitor 6 is reduced from the monitored power value Pₘₒₙ₅ to a monitored power value Pₘₒₙ₆ due to a change in operation of the circuit section 5. The frequency controller 10 determines that the signal value of the comparison result signal T_{cmp} is “1”, and the frequency controller 10 outputs, to the PLL controller 18, the frequency change instruction signal indicating the instruction to change the oscillation frequency of the PLL 20 to the second frequency Freq₂. Then, at a time indicated by an arrow H, the frequency of the PLL 20 is changed to the second frequency Freq₂, and the power consumed by the circuit section 5 reduced to a monitored power value Pₘₒₙ₇ due to the change in the frequency. The monitored power value Pₘₒₙ₇ is a value obtained by summing the base power value P_{base} and the offset power value P_{offset}, like the monitored power values Pₘₒₙ₃ and Pₘₒₙ₅.

Then, at a time indicated by an arrow I, the power consumed by the circuit section 5 and monitored by the power monitor 6 increases from the monitored power value Pₘₒₙ₇ to a monitored power value Pₘₒₙ₈ due to a change in operation of the circuit 5. The frequency controller 10 determines that the signal value of the comparison result signal T_{cmp} is “1”, and the frequency controller 10 outputs, to the PLL controller 18, the frequency change instruction signal indicating the instruction to change the oscillation frequency of the PLL 20 to the second frequency Freq₂. Then, at a time indicated by an arrow J, the frequency of the PLL 20 is changed to the second frequency Freq₂, and the power consumed by the circuit section 5 is reduced to a monitored power value Pₘₒₙ₉ due to the change in the frequency. The monitored power value Pₘₒₙ₉ is a value obtained by summing the base power value P_{base} and the offset power value P_{offset}, like the monitored power values Pₘₒₙ₃. Pₘₒₙ₅, and Pₘₒₙ₇.

After that, the frequency controller 10 controls the frequency of the PLL 20 so that the power consumed by the circuit section 5 is maintained at the value obtained by summing the base power value P_{base} and the offset power value P_{offset} until the frequency controller 10 determines that the signal value of the comparison result signal is “0”.

Effects of Semiconductor Device According to Embodiment

The semiconductor device 1 controls the operational frequency of the PLL 20 while treating, as the target power value, the value obtained by summing the offset power value P_{offset} and the exponential moving average power value Pₑₓₚ corresponding to a change in the temperature of the circuit section 5 when the temperature of the circuit section 5 reaches the temperature threshold Tₜₕ. Since the semiconductor device 1 treats, as the target power value, the value obtained by adding the offset power value P_{offset} to the exponential moving average power value Pₑₓₚ, the semiconductor device 1 may control the PLL with an operational frequency higher than that of the semiconductor device 900 that treats the exponential moving average power value Pₑₓₚ as the target power. Since the semiconductor device 1 may control the PLL with an operational frequency higher than that of the semiconductor device 900, a pointless reduction in the operational frequency of the semiconductor device may be inhibited.

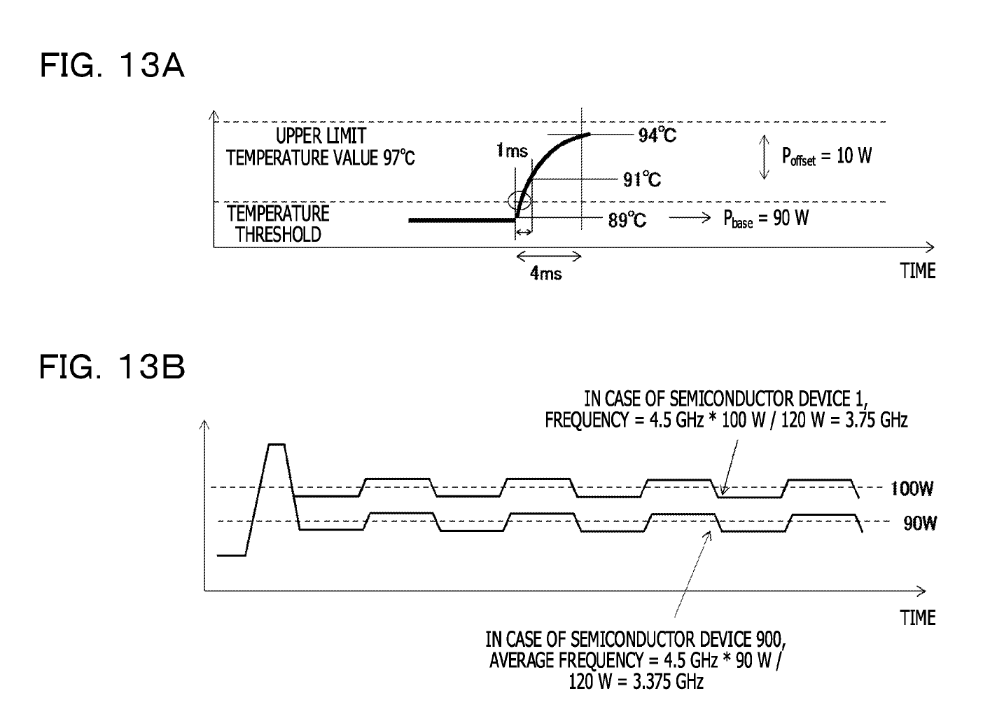

For example, as illustrated in FIG. 13A, it is assumed that the upper limit of the temperature of the semiconductor device is 97° C., a time period to the time when the frequency of the PLL 20 is controlled based on the detected temperature Tⱼ is 4 milliseconds, and a time period to the time when the frequency of the PLL 20 is controlled based on the monitored power value Pₘₒₙ is 1 millisecond. In addition, it is assumed that the base power value P_{base} and the offset power value P_{offset} that are obtained based on the control delay based on the detected temperature Tⱼ and the monitored power value Pₘₒₙ are 90 W and 10 W, respectively.

For example, it is assumed that the semiconductor device is controlled so that power consumed by the semiconductor device with a frequency of 4.5 GHz is 120 W. In this example, in the semiconductor device 900, the frequency of the PLL is adjusted to 3.375 GHz so that consumed power matches 90 W corresponding to the base power value P_{base} when the temperature of the circuit section exceeds the temperature threshold Tₜₕ. In this example, in the semiconductor device 1, the frequency of the PLL is adjusted to 3.75 GHz so that consumed power matches 100 W corresponding to the value obtained by summing the base power value P_{base} and the offset power value P_{offset} when the temperature of the circuit section exceeds the temperature threshold Tₜₕ. In this example, the semiconductor device 1 achieves approximately an 11% (=(3.75−3.375)/3.375) improvement in performance with respect to the semiconductor device 900.

Modified Example of Semiconductor Device According to Embodiment

In the semiconductor device 1, the frequency controller 10 includes the first frequency calculator 15 and the second frequency calculator 16 that include the same constituent sections other than the base power register 160 and do not operate simultaneously. Thus, in the semiconductor device according to the embodiment, the arithmetic sections of the first and second frequency calculators 15 and 16 may be made common and a selecting circuit may select the exponential moving average power value Pₑₓₚ and the base power value P_{base}. In this case, as a signal to be selected by the selecting circuit, a signal delayed by one cycle with respect to the comparison result signal T_{cmp} is used.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A semiconductor device comprising:
an oscillator that oscillates to generate a clock;
a circuit that operates based on the clock generated by the oscillator;
a temperature detector that detects the temperature of the circuit;
a power detector that acquires, as a monitored power value, power consumed by the circuit; and
a frequency controller that controls, when the temperature detected by the temperature detector exceeds a temperature threshold, the frequency of the clock of the oscillator so that the monitored power value matches target power that causes the temperature of the circuit to converge to a temperature higher than the temperature threshold.

2. The semiconductor device according to claim 1,
wherein the frequency controller includes
a power estimator that estimates, based on the monitored power value, a base power value corresponding to the temperature of the circuit when the temperature detected by the temperature detector matches the temperature threshold, and
a frequency determiner that determines the frequency of the clock so that the target power is equal to or higher than the base power value and equal to or lower than the monitored power value acquired when the temperature detected by the temperature detector exceeds the temperature threshold.

3. The semiconductor device according to claim 2,
wherein the frequency controller further includes a base power register for storing the base power value.

4. A method of controlling a semiconductor device including an oscillator that oscillates to generate a clock and a circuit that operates based on the clock generated by the clock, comprising:
causing a temperature detector included in the semiconductor device to detect the temperature of the circuit;
causing a power detector included in the semiconductor device to acquire, as a monitored power value, power consumed by the circuit; and
causing, when the temperature detected by the temperature detector exceeds a temperature threshold, a frequency controller included in the semiconductor device to control the frequency of the clock of the oscillator so that the monitored power value matches target power that causes the temperature of the circuit to converge to a temperature higher than the temperature threshold.
